(19) United States
(12) Patent Application Publication
(10) Pub. No.: US 2025/0377383 A1
(43) Pub. Date: Dec. 11, 2025

(54) CURRENT SENSOR CIRCUIT

(71) Applicant: SUMIDA CORPORATION, Tokyo (JP)

(72) Inventor: Hiroyuki MIYAZAKI, Natori City (JP)

(21) Appl. No.: 19/309,693

(22) Filed: Aug. 26, 2025

Related U.S. Application Data
(63) Continuation of application No. PCT/JP2023/007734, filed on Mar. 2, 2023.

(51) Int. Cl. G01R 15/18; G01R 19/00

(52) U.S. Cl. CPC G01R 15/18; G01R 19/0092

(57) ABSTRACT

A current sensor circuit includes a detection coil configured such that an inductance changes with a direct current, a resonant capacitor, a phase adjusting circuit that receives a feedback signal from the resonant capacitor and outputs a drive signal, a switching circuit that includes a plurality of switching elements forming a half-bridge circuit or a full-bridge circuit and supplies an alternating current signal to the detection coil and the resonant capacitor by causing the plurality of switching elements to perform a switching operation in accordance with a pulse period of the drive signal, a signal converting circuit that converts the drive signal output from the phase adjusting circuit into a detection signal indicating a change in the direct current, and a detection terminal that outputs the detection signal to the outside.

### CROSS REFERENCE TO RELATED APPLICATIONS

This application is a continuation under 35 U.S.C. § 120 of PCT/JP2023/007734, filed Mar. 2, 2023, which is incorporated herein by reference, and which claims priority thereof.

### TECHNICAL FIELD

The present invention relates to a current sensor circuit that detects a direct current.

### BACKGROUND ART

As a current sensor that detects a direct current in a non-contact manner, there is a current sensor using a Hall element, but there is a problem that the current cannot be accurately detected when noise is superimposed on a detection signal of the current.

Patent Document 1 below discloses a current sensor capable of measuring a direction of a current to be detected without using a Hall element. The current sensor includes a magnetic core for passing a magnetic flux by a current to be detected, a resonance circuit including a winding wound around the magnetic core, an oscillator that applies a signal of a predetermined frequency to the resonance circuit, an output circuit that is connected to the resonance circuit and outputs an electric signal corresponding to the direction of the current to be detected on the basis of a change in a characteristic of the resonance circuit that changes in accordance with the direction of the current to be detected, and a magnetic field bias unit that applies a magnetic field bias to the magnetic core.

### CITATION LIST

### Patent Document

Patent Document 1: JP 2012-37508 A

### SUMMARY OF THE INVENTION

### Problems to be Solved by the Invention

However, the current sensor described above still has room for improvement in current detection accuracy.

The present invention provides a current sensor circuit technology capable of detecting a direct current with high accuracy while suppressing the influence of noise.

### Means for Solving the Problem

According to the present invention, there is provided a current sensor circuit capable of detecting a direct current flowing through a conducting wire for detection, the current sensor circuit including: a detection coil configured such that an inductance changes with the direct current; a resonant capacitor that constitutes a series resonant circuit together with the detection coil; a phase adjusting circuit that receives a feedback signal from the resonant capacitor and outputs a drive signal; a switching circuit that includes a plurality of switching elements forming a half-bridge circuit or a full-bridge circuit and supplies an alternating current signal to the detection coil and the resonant capacitor by causing the plurality of switching elements to perform a switching operation in accordance with a pulse period of the drive signal; a signal converting circuit that converts the drive signal output from the phase adjusting circuit into a detection signal indicating a change in the direct current; and a detection terminal that outputs the detection signal to an outside, in which the phase adjusting circuit sets the pulse period of the drive signal in accordance with a phase difference between the feedback signal and the drive signal such that a frequency of the alternating current signal flowing through the detection coil and the resonant capacitor follows a resonant frequency of the series resonant circuit changed in accordance with an inductance change of the detection coil.

### Effect of the Invention

According to the above aspect, it is possible to provide a current sensor circuit technology capable of detecting a direct current with high accuracy while suppressing the influence of noise.

### BRIEF DESCRIPTION OF THE DRAWINGS

FIG. 1 is a circuit diagram of a current sensor circuit in the present embodiment.

FIG. 2 is a diagram conceptually illustrating a configuration example of a detection coil in the present embodiment.

FIG. 3 is an example of a circuit diagram of a pulse converting circuit.

FIG. 4 is a graph illustrating a relationship between an inductance change of a detection coil, a pulse frequency change of a drive signal, and a DC bias current.

FIG. 5A-FIG. 5C are diagrams illustrating signal waveforms at points A, B, C, and D of the current sensor circuit in the present embodiment.

FIG. 6 is a diagram conceptually illustrating a configuration of a detection coil in a modification.

FIG. 7 is a circuit diagram of a current sensor circuit according to a modification.

### DESCRIPTION OF EMBODIMENTS

Hereinafter, an embodiment of the present invention will be described. Note that the following embodiment is an example, and the present invention is not limited only to the configuration of the following embodiment.

### [Circuit Configuration]

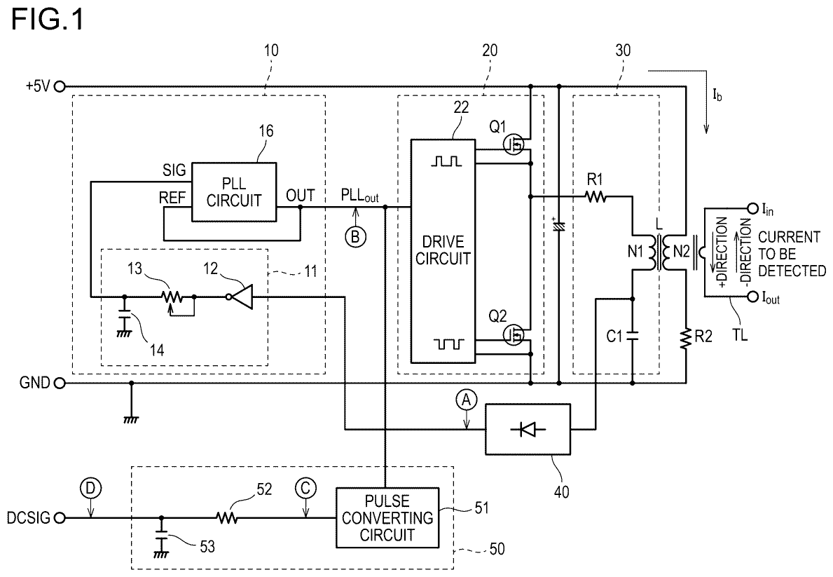

FIG. 1 is a circuit diagram of a current sensor circuit 1 in the present embodiment.

The current sensor circuit 1 includes a phase adjusting circuit 10, a switching circuit 20, a detection circuit 30, a feedback rectifier circuit 40, a signal converting circuit 50, a detection terminal DCSIG, a magnetic field bias unit, and the like.

The detection circuit 30 includes a resistance element R1, a detection coil N1, and a resonant capacitor C1 connected in series. Thus, the detection circuit 30 becomes a series resonant circuit by flow of an AC signal at a resonant frequency.

The detection coil N1 is configured such that its inductance changes when a direct current (also referred to as a current to be detected) flows through a conducting wire for detection of a measured system.

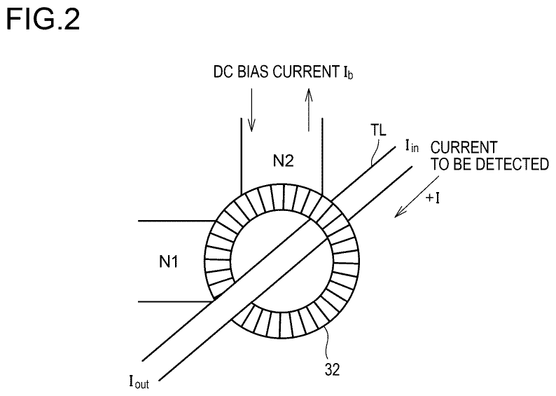

FIG. 2 is a diagram conceptually illustrating a configuration example of the detection coil N1 according to the present embodiment.

As illustrated in FIG. 2, the winding of the detection coil N1 is wound around a magnetic core 32 through which a conducting wire TL for detection is inserted. With such a configuration, when a direct current I flows through the conducting wire TL for detection, a magnetic flux in the magnetic core 32 is changed by a magnetic field generated around the conducting wire for detection TL, and the inductance of the detection coil N1 of which the winding is wound around the magnetic core 32 is changed with the change in the magnetic flux.

As long as the magnetic core 32 exerts such an action, a material thereof is not limited, such as a ferrite material or an electromagnetic steel sheet.

In addition, the magnetic core 32 illustrated in FIG. 2 is an annular core called a toroidal core and has the conducting wire TL for detection inserted through its center, but it is not limited to such a configuration as long as the above-described action is achieved.

Furthermore, a winding of a bias coil N2 is also wound around the magnetic core 32. The bias coil N2 constitutes a magnetic field bias unit and applies a magnetic field bias to the magnetic core 32 that can cause the magnetic core to reach a magnetic saturation region. Details of the magnetic field bias unit will be described later.

When the current I to be detected flows in a direction in which a magnetic flux in the same direction (overlapping direction) as the magnetic flux in the magnetic core 32 generated by a DC bias current Ib flowing through the bias coil N2 is generated, the inductance of the detection coil N1 decreases. On the other hand, when the current I to be detected flows in a direction in which a magnetic flux in the opposite direction (canceling direction) to the magnetic flux in the magnetic core 32 generated by the DC bias current Ib flowing through the bias coil N2 is generated, the inductance of the detection coil N1 increases.

In the present embodiment, a direction of the current I to be detected in which the inductance of the detection coil N1 decreases is set to a positive direction (+I), and a direction of the current I to be detected in which the inductance of the detection coil N1 increases is set to a negative direction (−I).

The switching circuit 20 includes a drive circuit 22, two transistors Q1 and Q2, and the like.

The transistors Q1 and Q2 in the present embodiment are field effect transistors (FETs) and can be referred to as switching elements.

In the example of FIG. 1, the transistors Q1 and Q2 are N-channel metal oxide semiconductor field effect transistors (MOSFET) and form a half bridge circuit. The detection circuit 30 is connected between the source and the drain of the transistor Q2.

The drive circuit 22 is connected to the transistors Q1 and Q2 such that gate-to-source voltages (hereinafter, it may be referred to as a V_{GS} voltage) of the transistors Q1 and Q2 can be applied thereto.

The drive circuit 22 alternately applies the V_{GS} voltage exceeding a threshold voltage to the transistor Q1 and the transistor Q2 to alternately switch on/off states of the transistor Q1 and the transistor Q2 (perform switching operation). At this time, the drive circuit 22 switches the on and off states of the transistors Q1 and Q2 in accordance with a pulse period of the drive signal from the phase adjusting circuit 10. Thus, an AC signal having a frequency corresponding to the cycle of the drive signal from the phase adjusting circuit 10 flows through the detection circuit 30. Although details will be described later, the pulse period of the drive signal from the phase adjusting circuit 10 is controlled such that an AC signal having a resonant frequency flows to the detection circuit 30.

The feedback rectifier circuit 40 is a circuit that performs half-wave rectification on the feedback signal from the detection circuit 30. Specifically, the feedback rectifier circuit 40 half-wave rectifies the AC voltage waveform applied to the resonant capacitor C1 and sends the half-wave rectified voltage waveform to the phase adjusting circuit 10.

The phase adjusting circuit 10 receives a feedback signal from the detection circuit 30 and outputs a drive signal. Specifically, the phase adjusting circuit 10 sets the pulse period of the drive signal to be output in accordance with a phase difference between the signal (feedback signal) obtained by half-wave rectifying the AC voltage waveform applied to the resonant capacitor C1 and the drive signal such that the frequency of the AC signal flowing to the detection circuit 30 follows the resonant frequency of the detection circuit 30 (series resonant circuit).

The phase adjusting circuit 10 includes a feedback pulse generating circuit 11, a phase locked loop (PLL) circuit 16, and the like.

The feedback pulse generating circuit 11 includes a NOT circuit 12, a variable resistance element 13, a capacitor 14, and the like. The NOT circuit 12 converts the half-wave rectified waveform from the feedback rectifier circuit 40 into a pulse waveform with a threshold voltage, and an RC filter formed of the variable resistance element 13 and the capacitor 14 corrects a deviation of the pulse waveform at the time of shaping. In this way, a feedback pulse signal (SIG pulse) converted from the half-wave rectified waveform from the feedback rectifier circuit 40 by the feedback pulse generating circuit 11 is sent to the PLL circuit 16.

The PLL circuit 16 compares the phases of the feedback pulse signal (SIG pulse) sent from the feedback pulse generating circuit 11 and the drive signal (REF pulse) and adjusts the pulse period of the drive signal (PLLout) as the output signal so as to eliminate the phase difference. The PLL circuit 16 may have a configuration of a known single-loop PLL circuit, and includes, for example, a frequency divider, a phase comparator, a filter, a voltage controlled oscillator (VCO), and the like. The drive signal output from the PLL circuit 16 is sent to each of the switching circuit 20 and the signal converting circuit 50 and is also looped and used as a reference signal (REF pulse).

The signal converting circuit 50 converts the drive signal output from the phase adjusting circuit 10 into a detection signal indicating a change in the direct current flowing through the conducting wire TL for detection. This detection signal is output from the detection terminal DCSIG to the outside.

The signal converting circuit 50 includes a pulse converting circuit 51, a resistance element 52, a capacitor 53, and the like. The pulse converting circuit 51 converts the drive signal output from the phase adjusting circuit 10 into a pulse frequency modulation (PFM) signal. The resistance element 52 and the capacitor 53 form an RC filter and smooths a PFM signal output from the pulse converting circuit 51 to obtain a voltage level waveform. This voltage level waveform is a detection signal indicating a change in the direct current flowing through the conducting wire TL for detection.

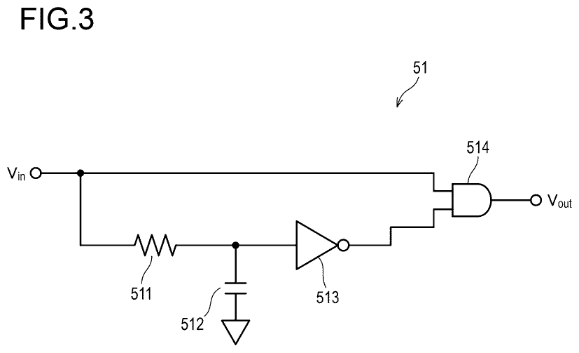

FIG. 3 is an example of a circuit diagram of the pulse converting circuit 51.

In the example of FIG. 3, the pulse converting circuit 51 is a monostable multivibrator circuit including a resistance element 511, a capacitor 512, a NOT circuit 513, an AND circuit 514, and the like. In the pulse converting circuit 51, the input drive signal and a signal in which a rising timing of the pulse of the input drive signal is shifted by the resistance element 511 and the capacitor 512 and inverted by the NOT circuit 513 are input to the AND circuit 514, so that a PFM signal having a constant pulse width and a duty ratio changing in proportion to the pulse period of the drive signal is output.

However, the configuration of the pulse converting circuit 51 is not limited to the configuration example illustrated in FIG. 3 and may be a monostable multivibrator circuit having another configuration.

The magnetic field bias unit includes the above-described bias coil N2 (see FIG. 2) and a DC power supply (not shown) that conducts a constant current to the bias coil N2. This DC power supply supplies DC power (+5 V in the example of FIG. 1) to the bias coil N2 having a winding wound around the magnetic core 32, thereby applying the magnetic field bias to the magnetic core 32 to cause the magnetic core to reach the magnetic saturation region. Thus, in the inductance characteristic of the detection coil N1 around which the winding is wound around the same magnetic core 32, a shift to a region where the inductance changes linearly occurs.

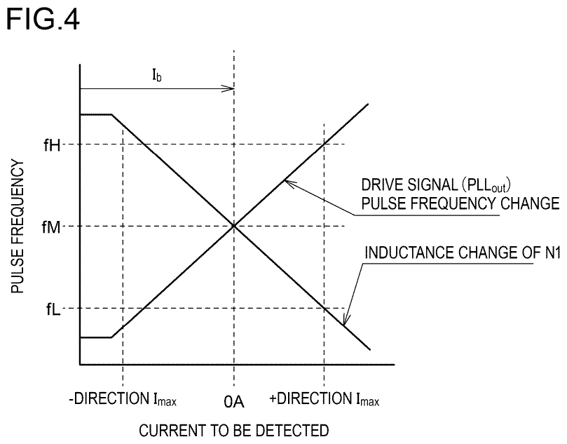

FIG. 4 is a graph illustrating the relationship between the inductance change of the detection coil N1, the pulse frequency change of the drive signal, and the DC bias current Ib. The horizontal axis of FIG. 4 represents the current I to be detected, and the vertical axis of FIG. 4 represents the pulse frequency (reciprocal of the pulse period) of the drive signal.

With the configuration exemplified in FIG. 2, the inductance of the detection coil N1 changes depending on the current I to be detected. As illustrated in FIG. 4, when the current I to be detected in the positive direction increases, the inductance of the detection coil N1 decreases, and when the current I to be detected in the negative direction increases, the inductance of the detection coil N1 increases. When the inductance of the detection coil N1 decreases, the resonant frequency of the detection circuit 30 increases, and accordingly, the pulse frequency of the drive signal also increases (the pulse period decreases). In addition, when the inductance of the detection coil N1 increases, the resonant frequency of the detection circuit 30 decreases, and accordingly, the pulse frequency of the drive signal also decreases (the pulse period increases).

On the other hand, the inductance change of the detection coil N1 is not a complete linear change. Therefore, in the present embodiment, the winding of the bias coil N2 is wound around the magnetic core 32 together with the detection coil N1, and the DC bias current is caused to flow through the bias coil N2 so as to cancel the non-linear region and perform shift to the linear region in the inductance characteristic of the detection coil N1.

Therefore, the output of the DC power supply of the magnetic field bias unit is set such that the inductance value of the detection coil N1 changes in the linear region within the measurable range (range from −Imax to +Imax) of the current I to be detected, and the inductance value of the detection coil N1 when the current I to be detected does not flow (zero amperes) becomes the median value of the linear change region.

### [Operation]

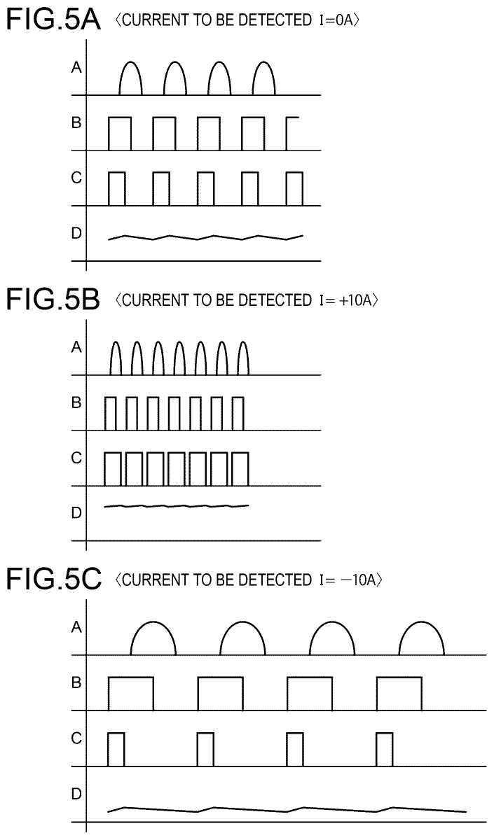

Next, the operation of the current sensor circuit 1 having the circuit configuration as described above will be described with reference to FIG. 5A to FIG. 5C. FIG. 5A to FIG. 5C are diagrams illustrating signal waveforms at points A, B, C, and D of the current sensor circuit 1 according to the present embodiment. The positions of points A, B, C, and D are as illustrated in FIG. 1. FIG. 5A illustrates a signal waveform when the current I to be detected is not flowing (0 (A)), FIG. 5B illustrates a signal waveform when the current I to be detected is +10 (A), and FIG. 5C illustrates a signal waveform when the current I to be detected is −10 (A).

When no current flows through the conducting wire TL for detection (FIG. 5A), the switching operation of the transistors Q1 and Q2 by the switching circuit 20 is performed in accordance with the pulse period of the drive signal output from the phase adjusting circuit 10 such that the detection circuit 30 becomes to be in the resonant state.

At this time, an AC voltage waveform (base signal) applied to the resonant capacitor C1 of the detection circuit 30 is a resonant frequency waveform, and this waveform signal is half-wave rectified by the feedback rectifier circuit 40. A waveform at the point A in FIG. 5A is a half-wave rectified waveform output from the feedback rectifier circuit 40.

Such a base signal (half-wave rectified waveform) is converted into a pulse waveform with a threshold voltage, further subjected to deviation correction in the feedback pulse generating circuit 11 of the phase adjusting circuit 10 and sent to the PLL circuit 16 as a feedback pulse signal. In the PLL circuit 16, the phases of the feedback pulse signal and the drive signal are compared, and the pulse period of the drive signal (PLLout) as the output signal is adjusted such that the phase difference is eliminated. A waveform at the point B in FIG. 5A is a waveform of the drive signal output from the phase adjusting circuit 10.

At this time, since no current flows through the conducting wire TL for detection, there is basically no phase difference, and the pulse period of the drive signal is maintained so as to correspond to the resonant frequency of the detection circuit 30.

The drive signal is transmitted to the switching circuit 20 and also to the signal converting circuit 50 and is converted into a PFM signal in the pulse converting circuit 51. A waveform at the point C in FIG. 5A is the PFM signal waveform.

This PFM signal is smoothed by the RC filter of the resistance element 52 and the capacitor 53 in the signal converting circuit 50 to be a voltage level waveform and can be output from the detection terminal DCSIG to the outside. A waveform at the point D in FIG. 5A is the voltage level waveform and indicates the voltage level corresponding to the current I to be detected being 0 (A).

When the current I to be detected of +10 (A) flows through the conducting wire TL for detection (FIG. 5B), the inductance of the detection coil N1 becomes smaller than that when the current I to be detected does not flow. Thus, in the detection circuit 30, the resonant frequency becomes high and a deviation from the resonant state occurs.

As a result, a phase difference occurs between the feedback pulse signal and the drive signal compared by the PLL circuit 16 of the phase adjusting circuit 10, and the pulse period of the drive signal is shortened (the pulse frequency is set high) by the PLL circuit 16 so as to reduce the phase difference. A waveform at the point B in FIG. 5B indicates the waveform of the drive signal adjusted in this manner.

When the switching circuit 20 performs the switching operation of the transistors Q1 and Q2 so as to correspond to the pulse period of the drive signal adjusted in this way, the frequency of the AC signal flowing through the detection circuit 30 follows the resonant frequency of the detection circuit 30 that has changed in accordance with the decrease in the inductance of the detection coil N1.

The drive signal thus adjusted is converted into a PFM signal in the pulse converting circuit 51 (a waveform at the point C in FIG. 5B), and the PFM signal is smoothed by the RC filter of the resistance element 52 and the capacitor 53 in the signal converting circuit 50 to be a voltage level waveform (a waveform at the point D in FIG. 5B). This voltage level waveform indicates a voltage level corresponding to that the current I to be detected is +10 (A).

When the current I to be detected of −10 (A) flows through the conducting wire TL for detection (FIG. 5C), the inductance of the detection coil N1 becomes larger than that when the current I to be detected does not flow. Thus, in the detection circuit 30, the resonant frequency becomes low and a deviation from the resonant state occurs.

As a result, a phase difference occurs between the feedback pulse signal and the drive signal compared by the PLL circuit 16 of the phase adjusting circuit 10, and the pulse period of the drive signal is lengthened (the pulse frequency is set low) by the PLL circuit 16 so as to reduce the phase difference. A waveform at the point B in FIG. 5C indicates the waveform of the drive signal adjusted in this manner.

When the switching circuit 20 performs the switching operation of the transistors Q1 and Q2 so as to correspond to the pulse period of the drive signal adjusted in this way, the frequency of the AC signal flowing through the detection circuit 30 follows the resonant frequency of the detection circuit 30 that has changed in accordance with the increase in the inductance of the detection coil N1.

The drive signal thus adjusted is converted into a PFM signal in the pulse converting circuit 51 (a waveform at the point C in FIG. 5C), and the PFM signal is smoothed by the RC filter of the resistance element 52 and the capacitor 53 in the signal converting circuit 50 to be a voltage level waveform (a waveform at the point D in FIG. 5C). This voltage level waveform indicates a voltage level corresponding to the current I to be detected of −10 (A).

As described above, in the present embodiment, the magnitude of the current I to be detected is captured by a change in the inductance of the detection coil N1 and a change in the resonant frequency of the detection circuit 30, the resonant frequency is tracked by the phase adjusting circuit 10, and the detection signal is generated from the drive signal output from the phase adjusting circuit 10.

As described above, in the present embodiment, since the circuit is operated so as to follow the resonant frequency of the detection circuit 30, a reaction to an external noise frequency can be suppressed. Furthermore, in the present embodiment, the noise resistance is improved by obtaining the detection signal from the PFM signal corresponding to the pulse duty ratio.

Therefore, according to the present embodiment, it is difficult to be affected by noise, and the detection level of the direct current can be maintained with high accuracy.

In addition, in the present embodiment, although there is a non-linear change region in the inductance characteristic of the detection coil N1, the winding of the bias coil N2 is wound around the magnetic core 32, which is also wound with the winding of the detection coil N1 and the DC bias current Ib is supplied to the bias coil N2, so that the non-linear change region is canceled and the inductance of the detection coil N1 is changed in the linear change region.

Thus, the magnitude of the current I to be detected can be detected with high accuracy.

Furthermore, as illustrated as the waveform at the point C in FIG. 5, the PFM signal output from the pulse converting circuit 51 is a signal having a constant pulse width regardless of the pulse period of the drive signal while being synchronized with the rising timing of the pulse of the drive signal (the waveform at the point B). That is, the drive signal output from the phase adjusting circuit 10 is a signal having a constant duty ratio and a pulse width proportional to the pulse period (pulse frequency), whereas the PFM signal is a signal having a constant pulse width and a duty ratio proportional to the pulse period (pulse frequency).

By converting into such a PFM signal, the smoothed signal can be a signal whose level rises and falls in accordance with the pulse period (pulse frequency), and can be a detection signal indicating a change in the current I to be detected.

### [Modification]

The contents of the above-described embodiments can be modified as appropriate.

For example, in a case where it is possible to detect whether or not a direct current has flowed through the conducting wire TL for detection or whether or not a direct current exceeding a predetermined current value has flowed through the conducting wire TL for detection at a detection current level at which an inductance change of the detection coil N1 occurs, the current sensor circuit 1 may not include the magnetic field bias unit. Further, the signal converting circuit 50 is not limited to the above configuration as long as the drive signal output from the phase adjusting circuit 10 can be converted into a detection signal that can indicate a change in the current to be detected. For example, in the signal converting circuit 50, the detection signal may be generated without being converted into the PFM signal.

Furthermore, in the above-described embodiment, an example has been described in which the magnetic field bias unit includes the bias coil N2 and the DC power supply, but the magnetic field bias unit may include a bias magnet. In this case, the bias coil N2 and the DC power supply (+5V) are unnecessary.

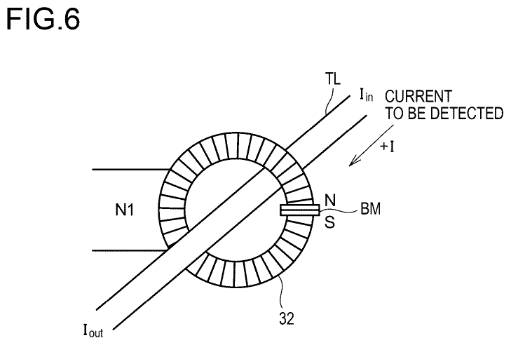

FIG. 6 is a diagram conceptually illustrating a configuration of a detection coil N1 according to a modification.

The present modification is similar to the above-described embodiment in that the winding of the detection coil N1 is wound around the magnetic core 32 and the conducting wire TL for detection is inserted through the magnetic core 32, but in the present modification, there is no winding of the bias coil N2, and instead, the bias magnet BM is provided in the magnetic core 32. Specifically, in the present modification, the magnetic core 32 is formed in a C-shape in which a part of an annular shape is interrupted, and the bias magnet BM is fitted into the interrupted gap to form an annular body as a whole.

The bias magnet BM applies to the magnetic core 32 a magnetic field bias that can cause the magnetic core to reach the magnetic saturation region. That is, the bias magnet BM has a magnetic force capable of causing a shift to a region (linear change region) in which the inductance changes linearly in the inductance characteristic of the detection coil N1.

Even if the magnetic field bias unit has such a configuration, it is possible to obtain the same operation and effect as those of the above-described embodiment.

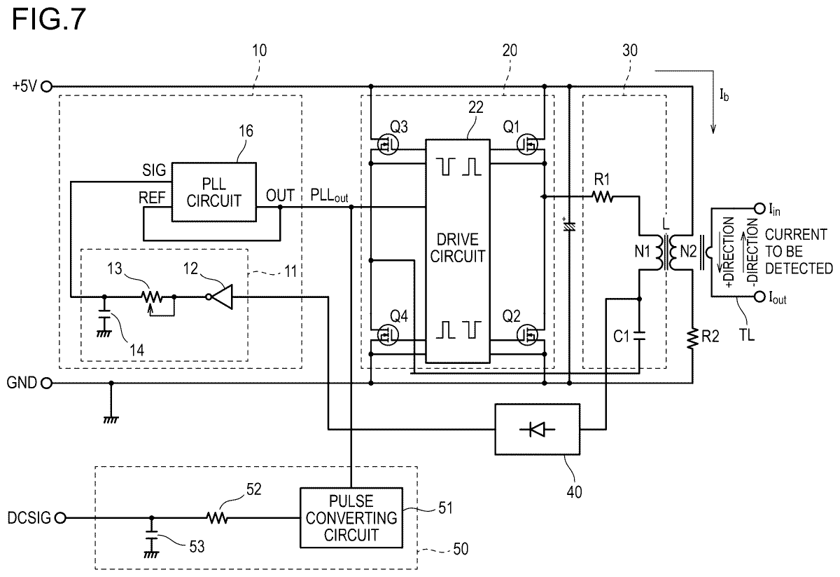

FIG. 7 is a circuit diagram of a current sensor circuit 1 according to a modification.

As illustrated in FIG. 7, the switching circuit 20 described above can be modified to include a plurality of transistors Q1, Q2, Q3, and Q4 forming a full-bridge circuit.

In the present modification, the drive circuit 22 is connected to the transistors Q1, Q2, Q3, and Q4 such that gate-to-source voltages (V_{GS} voltages) of the transistors Q1, Q2, Q3, and Q4 can be applied. Then, the drive circuit 22 alternately applies the V_{GS} voltage exceeding the threshold voltage to the pair of transistors Q1 and Q4 and the pair of transistors Q2 and Q3 in accordance with the pulse period of the drive signal from the phase adjusting circuit 10, thereby alternately switching the on and off states of the pair of transistors Q1 and Q4 and the pair of transistors Q2 and Q3 (switching operation).

Thus, similarly to the above-described embodiment, an AC signal having a frequency corresponding to the pulse period of the drive signal from the phase adjusting circuit 10 can flow to the detection circuit 30.

Some or all of the above-described embodiments and modifications can also be specified as follows. However, the above-described embodiments and modifications are not limited to the following description.

<1>

A current sensor circuit capable of detecting a direct current flowing through a conducting wire for detection, the current sensor circuit including:
a detection coil configured such that an inductance changes with the direct current;
a resonant capacitor that constitutes a series resonant circuit together with the detection coil;
a phase adjusting circuit that receives a feedback signal from the resonant capacitor and outputs a drive signal;
a switching circuit that includes a plurality of switching elements forming a half-bridge circuit or a full-bridge circuit and supplies an alternating current signal to the detection coil and the resonant capacitor by causing the plurality of switching elements to perform a switching operation in accordance with a pulse period of the drive signal;
a signal converting circuit that converts the drive signal output from the phase adjusting circuit into a detection signal indicating a change in the direct current; and
a detection terminal that outputs the detection signal to an outside, in which
the phase adjusting circuit sets the pulse period of the drive signal in accordance with a phase difference between the feedback signal and the drive signal such that a frequency of the alternating current signal flowing through the detection coil and the resonance capacitor follows a resonant frequency of the series resonant circuit changed in accordance with an inductance change of the detection coil.
   <2>

The current sensor circuit according to <1>, in which
the signal converting circuit includes a pulse converting circuit that converts the drive signal output from the phase adjusting circuit into a pulse frequency modulation (PFM) signal, and obtains the detection signal indicating a magnitude of the direct current with a magnitude of a voltage from the PFM signal.
   <3>

The current sensor circuit according to <1> or <2>, further including:
a magnetic core around which a winding of the detection coil is wound and through which the conducting wire for detection is inserted.
   <4>

The current sensor circuit according to <3>, further including:
a first magnetic field bias unit including a bias coil in which a winding is wound around the magnetic core and a DC power supply that conducts a constant current to the bias coil, or a second magnetic field bias unit including a bias magnet, in which
in the first magnetic field bias unit, the DC power supply conducts, to the bias coil, the constant current capable of causing a shift to a region in which inductance changes linearly in an inductance characteristic of the detection coil, and
in the second magnetic field bias unit, the bias magnet has a magnetic force capable of causing a shift to a region in which inductance changes linearly in an inductance characteristic of the detection coil.

### REFERENCE SIGNS LIST

1 Current sensor circuit
10 Phase adjusting circuit
11 Feedback pulse generating circuit
12 NOT circuit
13 Variable resistance element
14 Capacitor
16 PLL circuit
20 Switching circuit
22 Drive circuit
30 Detection circuit
32 Magnetic core
40 Feedback rectifier circuit
50 Signal converting circuit
51 Pulse converting circuit
52 Resistance element
53 Capacitor
DCSIG Detection terminal
511 Resistance element
512 Capacitor
513 NOT circuit
514 AND circuit
N1 Detection coil
N2 Bias coil
Q1, Q2, Q3, Q4 Transistor
R1 Resistance element
C1 Resonant capacitor
TL Conducting wire for detection
BM Bias magnet

1. A current sensor circuit capable of detecting a direct current flowing through a conducting wire for detection, the current sensor circuit comprising:
a detection coil configured such that an inductance changes with the direct current;
a resonant capacitor that constitutes a series resonant circuit together with the detection coil;
a phase adjusting circuit that receives a feedback signal from the resonant capacitor and outputs a drive signal;
a switching circuit that includes a plurality of switching elements forming a half-bridge circuit or a full-bridge circuit and supplies an alternating current signal to the detection coil and the resonant capacitor by causing the plurality of switching elements to perform a switching operation in accordance with a pulse period of the drive signal;
a signal converting circuit that converts the drive signal output from the phase adjusting circuit into a detection signal indicating a change in the direct current; and
a detection terminal that outputs the detection signal to an outside, wherein
the phase adjusting circuit sets the pulse period of the drive signal in accordance with a phase difference between the feedback signal and the drive signal such that a frequency of the alternating current signal flowing through the detection coil and the resonant capacitor follows a resonant frequency of the series resonant circuit changed in accordance with an inductance change of the detection coil.

2. The current sensor circuit according to claim 1, wherein
the signal converting circuit includes a pulse converting circuit that converts the drive signal output from the phase adjusting circuit into a pulse frequency modulation (PFM) signal, and obtains the detection signal indicating a magnitude of the direct current with a magnitude of a voltage from the PFM signal.

3. The current sensor circuit according to claim 1, further comprising:
a magnetic core around which a winding of the detection coil is wound and through which the conducting wire for detection is inserted.

4. The current sensor circuit according to claim 3, further comprising:
a first magnetic field bias unit including a bias coil in which a winding is wound around the magnetic core and a DC power supply that conducts a constant current to the bias coil, or a second magnetic field bias unit including a bias magnet, wherein
in the first magnetic field bias unit, the DC power supply conducts, to the bias coil, the constant current capable of causing a shift to a region in which inductance changes linearly in an inductance characteristic of the detection coil, and
in the second magnetic field bias unit, the bias magnet has a magnetic force capable of causing a shift to a region in which inductance changes linearly in an inductance characteristic of the detection coil.
